(19) United States
(12) Patent Application Publication
(10) Pub. No.: US 2007/0230275 A1
(43) Pub. Date: Oct. 4, 2007

(54) Method for manufacturing an ultrasound test head with an ultrasonic transducer configuration with a curved send and receive surface

(75) Inventors: Rainer Meier, Erlangen (DE); Thomas Rehfeldt, Erlangen (DE)

Correspondence Address: LERNER GREENBERG STEMER LLP, P O BOX 2480, HOLLYWOOD, FL, 33022-2480, US

(73) Assignee: intelligeNDT Systems & Services GmbH Co. KG

(21) Appl. No.: 11/713,820

(22) Filed: Mar. 2, 2007

(30) Foreign Application Priority Data
Mar. 4, 2006 (DE) 10 2006 010 009.3

(51) Int. Cl. B06B 1/06; H01L 41/00

(52) U.S. Cl. 367/140; 310/311

(57) ABSTRACT

A method for producing an ultrasonic test head having an ultrasonic transducer arrangement (200) with a curved transceiving surface (23) that is constructed from a plurality of juxtaposed transducer elements (14), comprises in accordance with the invention the following method steps:

a) a piezoelectric planar plate (2) corresponding to the external dimensions of the ultrasonic transducer arrangement is bonded with one of its flat sides (2a) on to a film (4) made from a polymer,
b) introduced into the flat side (2b), averted from the film (4), of the piezoelectric plate (2) before or after the bonding on to the film (4) are grooves (12) whose depth corresponds at least approximately to the thickness of the plate (2) such that a planar ultrasonic transducer arrangement (20) is produced that consists of a plurality of juxtaposed transducer elements (14), and
c) the planar ultrasonic transducer arrangement (20) is subsequently mounted with its flat side (2a) bonded to the film (4) on a curved bearing surface of a bending device (22) and bent there into a curved shape.

Method for producing an ultrasonic test head having an ultrasonic transducer arrangement with a curved transceiving surface

The invention relates to a method for producing an ultrasonic test head having an ultrasonic transducer arrangement with a curved transceiving surface.

Workpieces produced, in particular, from fiber composite materials such as, for example, glass fiber reinforced or carbon fiber reinforced plastics (GFR and CFR, respectively) can exhibit high porosity or delaminations depending on the production method respectively selected. This constitutes a substantial problem in the case, in particular, of safety-relevant components subjected to high mechanical stresses.

A method for determining the porosity of a fiber composite material in the case of which an ultrasonic signal is coupled into the component and the amplitude of the back wall echo signal is detected and compared with the corresponding signals of an acceptable component is known from Gundtoft, Hans Erik, “Quantitative material characterisation of composites by ultrasonic scanning”, 15^{th} WCNDT Conference Rome 2000, published on the Internet at the address of www.ndt.net/article/wcndt00/papers/idn531/idn531.htm. A relatively low amplitude of the back wall echo signal is an indication in this case of the presence of porous sites inside the component.

Correcting the back wall echo signal with the aid of a so called wavelet analysis, in which case the porosity is assessed by using the ratio between the amplitude of the entry echo signal and the amplitude of the corrected back wall echo signal, is known from Shark L.-K., Yu, C., “Automatic estimation of ultrasonic attenuation for porosity evaluation in composite material”, 15^{th} WCNDT Conference Rome 2000.

However, the known methods assume that the components to be tested have a planar surface and a back wall essentially parallel thereto, in order to obtain a back wall echo that can be evaluated. However, a particular problem is posed especially by the automated testing of components in nonplanar regions that are particularly prone to faults for reasons of production engineering, for example in curved radial regions. As heretofore, it is necessary to carry out manual testing with the aid of individual oscillating test heads in order to obtain reliable test results in these regions, as well.

In order to enable a largely automated testing in these curved regions, it is possible in principle to use test heads that include an ultrasonic transducer arrangement that is constructed from a plurality of juxtaposed transducer elements, and whose transceiving surface is adapted to the curved surface geometry of the workpiece. The production of such an ultrasonic transducer arrangement is, however, problematic, since the piezoelectric starting bodies normally used consist of a ceramic composite material and are present in the form of planar plates that break very easily upon being bent. The risk of a breakage is particularly high when grooves have been introduced into the starting body in order in this way to produce an ultrasonic transducer arrangement (array) constructed from individual transducer elements largely separated from one another acoustically.

It is the object of the invention to specify a method for producing an ultrasonic test head having an ultrasonic transducer arrangement with a curved transceiving surface that is constructed from a plurality of juxtaposed transducer elements and with the aid of which the abovementioned difficulties are avoided.

The said object is achieved in accordance with the invention with the aid of a method having the features of patent claim 1 and comprising the following method steps:

a) a piezoelectric planar plate corresponding to the external dimensions of the ultrasonic transducer arrangement is bonded with one of its flat sides on to a film made from a polymer,
b) introduced into the flat side, averted from the film, of the piezoelectric plate before or after the bonding on to the film are grooves whose depth corresponds at least approximately to the thickness of the plate such that a planar ultrasonic transducer arrangement is produced that consists of a plurality of juxtaposed transducer elements, and
c) the planar ultrasonic transducer arrangement is subsequently mounted with its flat side bonded to the film on a curved bearing surface of a bending device and bent there into a curved shape.

Since the ultrasonic transducer arrangement (array) formed from the piezoelectric plate by introducing grooves is located during the bending operation on a film to which it is firmly bonded, the ultrasonic transducer arrangement is prevented from breaking apart into loose individual parts even when the transducer elements still cohering at the base of the groove break apart upon being bent at the base of the groove. It is possible in this way without any problem to produce ultrasonic test heads that are optimized for the respective test task and whose ultrasonic transducer arrangements exhibit a transceiving surface adapted to the respective surface shape of the component to be tested.

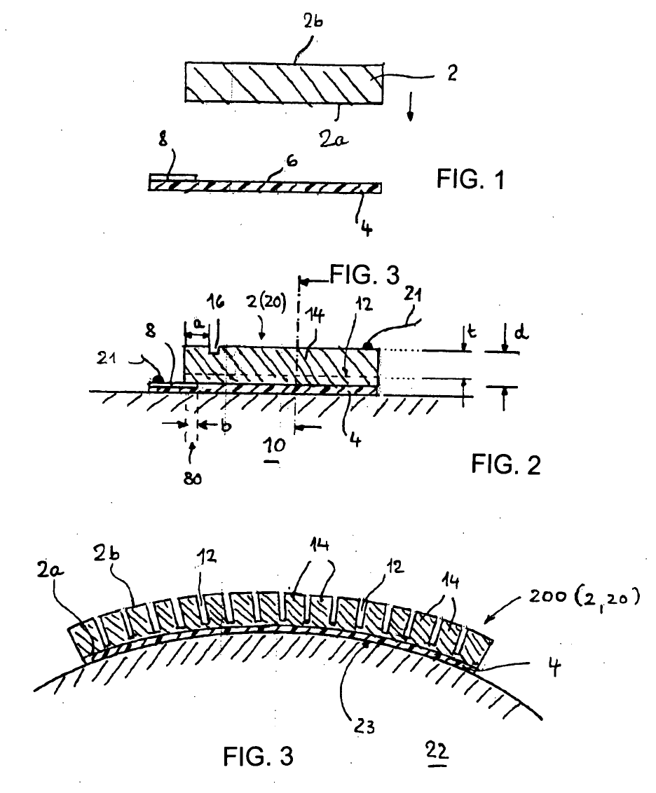

Further advantageous refinements of the method are specified in the subclaims. Reference is made to the exemplary embodiment of the drawing for the purpose of further explanation of the invention. In the drawing: FIGS. 1 to 4 respectively show in a schematic sectional view in temporary sequential steps essential method steps in the production of an ultrasonic test head in accordance with the invention.

In accordance with FIG. 1, a piezoelectric plate 2 is bonded with one of its planar flat sides 2a on to a thin film 4 consisting of a polymer. In the example, the film 4 consists of PVDF (polyvinylidene fluoride) and is typically approximately 0.1 mm thick and serves at the same time as a λ/4 matching layer in order to match the acoustic impedance of the plate 2 consisting of a piezoceramic composite material to a coupling medium, generally water, used in test situations. The thickness of the plate 2 itself is approximately 0.3 mm.

The film 4 is provided on its flat side 6 facing the plate 2 with an electrically conductive layer (not illustrated in the figure) whose thickness is in the submicrometer range. An electrically conductive contact strip 8, consisting of silver, for example, whose thickness is only a few μm and which extends in a longitudinal direction of the plate 2, or of the film 4, perpendicular to the plane of the drawing is attached at the edge of the film 4. The piezoelectric plate 2 is likewise provided with an electrically conductive layer (not illustrated in the figure) at its flat sides 2a, b. The contact strip 8 serves for providing ground contact in a later fabrication step.

In accordance with FIG. 2, the piezoelectric plate 2 which is bonded to the electrically conductive film 4 is fixed for the purpose of further processing on a saw table 10, for example being detachably bonded thereon. Starting from the flat side 2b (contacting or back side), opposite the electrically conductive film 4, of the piezoelectric plate 2, in a next machining step a plurality of narrow grooves 12, which are approximately 50 μm wide and extend in a fashion perpendicular to the flat side 2b into the interior of the plate 2, are introduced by saw cuts that run parallel to the narrow side of the plate 2 and parallel to the plane of the drawing, and whose depth t corresponds approximately to the thickness d of the plate 2. In the exemplary embodiment, the grooves 12 divide the plate 2 into a multiplicity of transducer elements 14 juxtaposed in a longitudinal direction extending perpendicular to the plane of the drawing, such that a linear planar ultrasonic transducer arrangement 20 is produced.

Introduced into the piezoelectric plate 2 on the flat side 2b in the vicinity of its edge and in a fashion parallel to its long side extending perpendicular to the plane of the drawing is a narrow longitudinal groove 16 that runs parallel to the contact strip 8 at a spacing a from the edge of the plate 2 that is greater than the width b of a region 80 in which the contact strip 8 makes contact with the plate 2. The part, located above the contact strip 8, of the piezoelectric plate 2 on the contacting side is in this way electrically separated from the transducer elements 14 such that disturbances in the acoustic field in the region of the contact strip 8 are avoided. The saw cut required to this end has only a slight depth, required for a contact separation, in order to avoid breakage of the plate 2 at this site. In the exemplary embodiment illustrated, in this fabrication step both the contact strip 8 and the contacting side, opposite the film 4, of each transducer element 14 makes contact with contact wires 21 made from copper.

It is also possible in principle to introduce the grooves 12 and 16 into the plate 12 before they are bonded to the film 4.

After introduction of the grooves 12 and the longitudinal groove 16, the ultrasonic transducer arrangement 20 is detached from the saw table 10 and brought to a bending apparatus 22, which is illustrated in FIG. 3 and whose surface has, in the example, a convex curvature that corresponds to that correspondingly concave curvature that a transceiving surface 23 of the ultrasonic transducer arrangement 200 is to exhibit in the final state. FIG. 3 illustrates a situation in which the transducer elements 14 of the ultrasonic transducer arrangement 200 are also still cohering in the bent state. Even when the transducer elements 14 break apart at the base of the grooves 12, something which can both be the case without being desired and can be intended, they are held by the film 4 such that the ultrasonic transducer arrangement 200 does not disintegrate into individual elements.

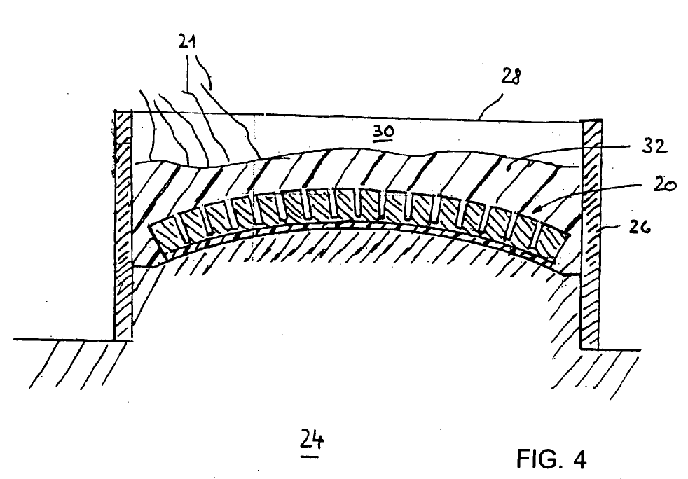

The bent ultrasonic transducer arrangement 200 is removed from the bending apparatus 22 and clamped over a fabrication apparatus 24 in accordance with FIG. 4. In this fabrication apparatus 24, a housing part 26 is pushed with an accurate fit over the ultrasonic transducer arrangement 200, and fastened on the fabrication apparatus 24. A cavity 30 located between the rear side of the ultrasonic transducer arrangement 200 and the top edge of the housing part 26 is now filled with a curable damping compound 32. After curing of the damping compound 32, the ultrasonic transducer arrangement 200 is removed in common with the housing 26. The latter is sealed by a cover, and the ultrasonic test head is finished after fastening of the connecting cable.

Instead of the mode of procedure sketched in FIG. 2, the rear sides of the transducer elements 14, and the contact strip 8 that is not visible in FIG. 3, can also make contact with contact wires 21 in the bending apparatus 22 or in the fabrication apparatus 24.

In the exemplary embodiment illustrated, the production of a concavely curved ultrasonic transducer arrangement is explained, the transducer elements being arranged juxtaposed along a curved line (curved linear array) in this case. However, the invention is also suitable in principle for producing convexly curved “linear” ultrasonic transducer arrangements, or convexly or concavely curved “two-dimensionally” ultrasonic transducer arrangements (curved matrix-shaped array).

### LIST OF REFERENCE NUMERALS

2 Piezoelectric plate
2a,b Flat side
4 Film
6 Flat side
10 Saw table
12 Groove
14 Transducer element
16 Longitudinal groove
20 Planar ultrasonic transducer arrangement
21 Contact wire
22 Bending apparatus
23 Transceiving surface
24 Fabrication apparatus
26 Housing part
30 Cavity
32 Damping compound
80 Region
200 Bent ultrasonic transducer arrangement
a Spacing
b Width
t Depth
d Thickness

1-6. (canceled)

7. A method for producing an ultrasonic test head having an ultrasonic transducer configuration with a curved transceiving surface constructed from a plurality of juxtaposed transducer elements, the method which comprises the following method steps:
a) bonding a flat side of a piezoelectric planar plate corresponding to external dimensions of the ultrasonic transducer configuration onto a film made from a polymer;
b) introducing grooves into a flat side, averted from the film, of the piezoelectric plate before or after the step of bonding onto the film, wherein a depth of the grooves corresponds substantially to a thickness of the plate, to thereby form a planar ultrasonic transducer configuration formed with a plurality of juxtaposed transducer elements; and
c) subsequently mounting the planar ultrasonic transducer configuration with the flat side bonded to the film on a curved bearing surface of a bending device and bending the transducer configuration thereupon into a curved shape.

8. The method according to claim 7, which comprises coating the film in an electrically conductive fashion on a flat side facing the plate.

9. The method according to claim 7, wherein the plate has a long side and a narrow side, and the method comprises laying an electrically conductive contact strip in between the plate and the film parallel to the long side and at an edge of the plate.

10. The method according to claim 9, which comprises forming, in addition to the grooves extending parallel to the narrow sides and effecting a separation of the transducer elements, forming a longitudinal groove extending at the edge of the plate parallel to a long side thereof at a spacing from the edge of the plate that is greater than a width of a region wherein the contact strip makes contact with the plate, on the flat side of the plate averted from the film.

11. The method according to claim 7, which comprises breaking the plate apart at a base of the grooves upon being bent.

12. The method according to claim 7, which further comprises:
d) clamping the bent ultrasonic transducer configuration into a fabrication apparatus and providing the transducer configuration with contact wires in this production stage, at the latest, and
e) subsequently pushing a prefabricated housing part over the contacted, bent ultrasonic transducer configuration and fixing in the fabrication apparatus; and
f) filling a cavity located between the flat side, averted from the film, of the bent ultrasonic transducer configuration and the top edge of the housing part with a curable damping compound.
